(19) United States
(12) Patent Application Publication
(10) Pub. No.: US 2025/0202196 A1
(43) Pub. Date: Jun. 19, 2025

(54) QUANTUM CASCADE LASER OPTICAL FREQUENCY COMB

(71) Applicant: ALPES LASERS S.A., St-Blaise (CH)

(72) Inventors: Antoine MÜLLER, Neuchâtel (CH); Richard MAULINI, Marin-Epagnier (CH); Sargis HAKOBYAN, Boudry (CH)

(73) Assignee: ALPES LASERS S.A., St-Blaise (CH)

(21) Appl. No.: 18/844,445

(22) PCT Filed: Mar. 1, 2023
(86) PCT No.: PCT/IB2023/000035

§ 371 Date: Sep. 6, 2024

Related U.S. Application Data
(60) Provisional application No. 63/317,926, filed on Mar. 8, 2022.

(51) Int. Cl. H01S 5/10; H01S 5/34; H01S 5/343

(52) U.S. Cl. CPC H01S 5/1046; H01S 5/3402; H01S 5/34313

(57) ABSTRACT

This invention concerns the design of an optical frequency comb, i.e. a laser whose spectrum consists of a series of discrete, equally spaced frequency lines, based on a quantum cascade laser (QCL), in particular to a waveguide design which controls the dispersion. To achieve this, the active region of the laser is sandwiched between two highly doped plasmon layers. This novel structure is particularly advantageous for mass-produced optical frequency comb QCLs.

### FIELD OF THE INVENTION

This invention relates to optical frequency combs based on quantum cascade lasers (QCLs), in particular to a waveguide design method to achieve dispersion compensation in such devices. A frequency comb is a laser source whose spectrum consists of a series of discrete, equally spaced frequency lines. Such frequency combs are used, e.g., for laserbased spectroscopy, metrology and microwave signal generation.

### BACKGROUND OF THE INVENTION

Since the invention of optical frequency combs, they have become an indispensable part of systems such as dual comb spectroscopy, metrology, and ultra-low noise microwave signal generation. The demonstration of the first Quantum Cascade Laser (QCL) frequency comb by ETH Zurich and Alpes Lasers SA in 2012 allowed the well-developed technologies of frequency combs to apply in the mid-infrared (mid-IR) region of the electromagnetic spectrum, as described by A. Hugi et al. in “Mid-infrared frequency comb based on a quantum cascade laser”, Nature 492, 229-233 (2012) and by G. Villares et al. in “Dual-comb spectroscopy based on quantum-cascade-laser frequency combs”, Nat. Commun. 5, 5192 (2014).

This spectral region is particularly interesting for chemical sensing applications based on spectroscopy, including industrial process monitoring, environmental monitoring and remote sensing applications, since many molecules have strong absorption lines in the mid-IR range (4-12 μm). QCLs are ideal laser sources for this spectral range. The central emission wavelength can be tuned to any wavelength between 4 and 12 μm by adjusting the design of the active region. One of the main challenges for the generation of frequency combs in QCLs remains the dispersion control of the system that has to be tuned to be close to zero for efficient phase locking of the modes to generate frequency comb teeth by four-wave mixing. This issue becomes even more challenging in short wavelength QCLs, as the material resonance absorption frequencies make the dispersion of the material extremely high and difficult to reduce. This was described by Y. Bidaux et al in “Coupled-Waveguides for Dispersion Compensation in Semiconductor Lasers”, Laser & Photonics Rev. 12, 1700323 (2018).

A significant amount of research has been conducted to address this issue. Various solutions have been proposed and demonstrated, including an external Gires-Tournois interferometer (GTI) mirror, described by J. Hillbrand et al. in “Tunable dispersion compensation of quantum cascade laser frequency combs”, Opt. Lett. 43, 1746-1749 (2018).

Other solutions included dispersion-compensating facet coatings, as described by G. Villares et al. in “Dispersion engineering of quantum cascade laser frequency combs”, Optica 3, 252-258 (2016) or by Q. Y. Lu et al. in “Shortwave quantum cascade laser frequency comb for multi-heterodyne spectroscopy”, Appl. Phys. Lett. 112, 1-5 (2018).

Further solutions include coupled dual waveguide geometry as described by Y. Bidaux et al in “Coupled-Waveguides for Dispersion Compensation in Semiconductor Lasers”, Laser & Photonics Rev. 12, 1700323 (2018) and disclosed in U.S. Pat. No. 11,070,030 B2, “Waveguide Heterostructure for Dispersion Compensation in Semiconductor Lasers”, by J. Faist et al.

However, all the technologies mentioned above either exert difficulties of fabrication (as possible mass fabrication), or are challenging for dispersion control:

The utilization of an external GTI mirror, as described by J. Hillbrand et al. in “Tunable dispersion compensation of quantum cascade laser frequency combs”, Opt. Lett. 43, 1746-1749 (2018), requires very precise positioning and mechanical stability to achieve and maintain the desired effect.

GTI mirror facet coatings, as described by G. Villares et al. in “Dispersion engineering of quantum cascade laser frequency combs”, Optica 3, 252-258 (2016), on the other hand, have the advantage of being monolithically integrated with the QCL chip but their fabrication requires the deposition of thick multilayer coatings on the QCL facets which is challenging in the mid-infrared spectral range where standard coating materials are not transparent. Furthermore, a different coating structure is required for each wavelength and each cavity length.

The dual waveguide geometry described by Y. Bidaux et al in “Coupled-Waveguides for Dispersion Compensation in Semiconductor Lasers”, Laser & Photonics Rev. 12, 1700323 (2018) requires the epitaxial growth of passive InGaAs waveguide in addition to the waveguide created by the QCL active region and the processing of said passive waveguide in buried heterostructure geometry. As a result, the wafer fabrication requires significantly more steps than that of standard QCLs. Another drawback of the dualwaveguide approach is that its heat dissipation capacity is lower than standard QCLs, because of the low thermal conductivity of InGaAs compared to InP. This leads to a higher active region temperature during operation and, hence, lower performance.

Plasmon-enhanced dispersion-controlled QCL combs have proven to be robust and reproducible designs for efficient QCL frequency comb fabrication, as described by Y. Bidaux et al in “Plasmon-enhanced waveguide for dispersion compensation in mid-infrared quantum cascade laser frequency combs”, Opt. Lett. 42, 1604-1607 (2017) and by S. Hakobyan and R. Maulini in “High performance quantum cascade laser frequency combs at λ˜6 μm based on plasmon-enhanced dispersion compensation”, Opt. Express 28, 20714-20727 (2020).

Different groups worked previously on plasmon-enhanced dispersion compensation as described by Y. Bidaux, R. Maulini, A. Muller et al in “Plasmon-enhanced waveguide for dispersion compensation in mid-infrared quantum cascade laser frequency combs”, Opt. Lett. 42, 1604-1607 (2017). Also, S. Hakobyan, R. Maulini, A. Muller et al. addressed this issue in “High performance quantum cascade laser frequency combs at λ˜6 μm based on plasmon-enhanced dispersion compensation”, Opt. Express 28, 20714-20727 (2020). However, both these documents show just one plasmon layer above the active region.

However, for short wavelength QCL combs (4-6 μm) this technology would not work due to the limitations in the doping concentration, and induced losses to the system, as well described by Y. Bidaux et al in “Coupled-Waveguides for Dispersion Compensation in Semiconductor Lasers”, Laser & Photonics Rev. 12, 1700323 (2018).

Thus, the main object of the present invention is to devise a dispersion-compensating waveguide design for short wavelength QCL combs which is suitable for mass production.

### SUMMARY OF THE INVENTION

The new waveguide design for dispersion-compensating QCLs is schematically represented in FIG. 1. To control the dispersion, the waveguide contains two highly doped n⁺-InP plasmon layers located above and below the active region, respectively. These two plasmon layers are separated from the active region by two low doped n-InP spacer layers.

By adjusting the carrier concentrations and thicknesses of these two highly doped n⁺-InP layers and the thicknesses of the n-InP spacer layers that separate them from the active region, the group velocity dispersion in the waveguide can be lowered to values below 500 fs²/mm which are required for the generation of optical frequency combs.

The production of dispersion-compensating double-plasmon waveguides according to the invention does not require additional fabrication steps compared to standard QCLs. The lower plasmon and spacer layers are grown during the same epitaxial growth step as the active region.

Since QCL combs according to the invention rely on intracavity dispersion compensation, no special facet coatings nor external mirrors are required. Comb generation is obtained from QCL chips of various lengths with as-cleaved facet and with regular (i.e. nondispersion-compensating) high reflectivity coatings.

Unlike the dual waveguide design referenced above, the inventive design does not require using low thermal conductivity alloys such as InGaAs, hence heat dissipation is not affected.

These two highly doped n⁺-InP layers located above and below the active region, so-to-speak sandwiching the active region, are a novel, inventive structure and particularly advantageous for mass-produced frequency comb QCLs.

### BRIEF DESCRIPTION OF THE DRAWINGS

In the attached drawings show:

FIG. 1 schematic of the novel QCL according to the invention

FIGS. 2a-2c three diagrams showing electric field distributions

FIGS. 2d-2f three diagrams showing effects of the novel QCL

FIG. 3 LIV curves for various temperatures

FIG. 4 optical spectrum and relative power of the novel QCL

FIG. 5 dispersion and losses of different novel QCLs at 4 μm

FIG. 6 frequency comb operation map of the novel QCL

### DETAILED DESCRIPTION OF THE INVENTION

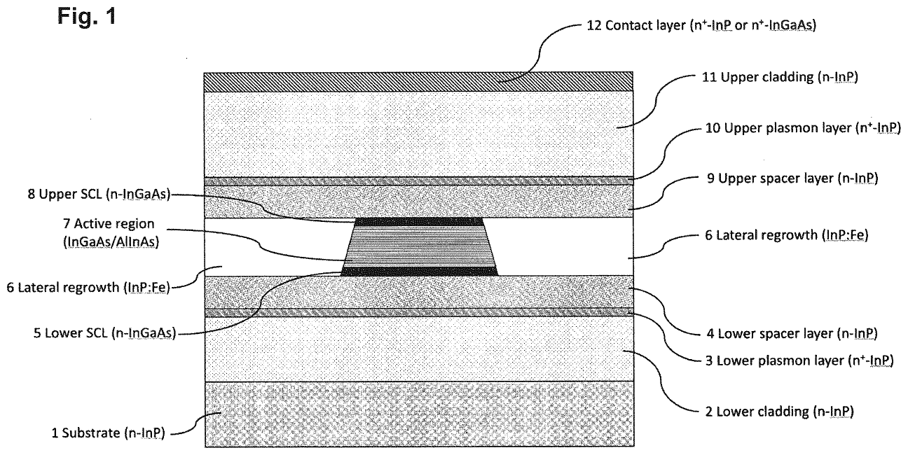

As shown schematically in FIG. 1, the waveguide is of the buried-heterostructure (BH) type. The following layers are grown on an n-InP substrate in a first epitaxial growth process:
n-InP substrate 1,
n-InP lower cladding 2,
n⁺-InP lower plasmon layer 3,
n-InP lower spacer layer 4,
n-InGaAs lower separate confinement layer (SCL) 5,
InGaAs/AlInAs superlattice active region 7, and
n-InGaAs upper SCL 8.

The purpose of the SCLs 5 and 8 is to increase the overlap between the optical mode and the active region. Though improving the function, they are not necessary. The invention can be realized with two SCLs, i.e. one below the active region and one above the active region as shown above. It can also be realized with only one SCL below the active region, or with only one above the active region, or even without any SCLs.

Also, the n-InP lower cladding layer 2 is not necessary. It can be replaced by appropriately doping the substrate 1 so that the growth process starts with the lower plasmon layer 3.

After the first growth process step, the active region 7 and (possibly the SCLs) are etched in mesas and semi-insulating InP:Fe 6 is selectively regrown on the sides to provide current confinement and waveguiding.

Finally, the remaining layers are grown in a third growth process step:
n-InP upper spacer layer 9,
n+-InP upper plasmon layer 10,
n-InP upper cladding 11 and
n+-InP or n+-InGaAs contact layer 12.

Although the lower and upper claddings, 2 and 11, resp., are shown as single layers in FIG. 1, they are usually composed of several InP layers with various doping levels.

Though there are variations of existence, number and/or position of many layers possible, the two plasmon layers 3 and 10 are essential parts of the invention.

In a first embodiment of the invention, a highly efficient optical frequency comb QCLwith emission spectrum centered at 5.3 μm, exhibiting up 350 mW of optical power and 55 cm⁻¹ of optical bandwidth was demonstrated. The QCL shows a stable frequency comb operation at measured temperatures from −10° C. to 50° C. and at almost all currents. In particular, this novel design showed good dispersion compensation at wavelengths down to 4 μm.

It is understood that the embodiment described here is only an example and that one skilled in the art may utilize other embodiments without departing from the scope of this invention.

The design of the novel waveguide structure was motivated by the previous work done by different groups on plasmon-enhanced dispersion compensation as described by Y. Bidaux, R. Maulini, A. Muller et al in “Plasmon-enhanced waveguide for dispersion compensation in mid-infrared quantum cascade laser frequency combs”, Opt. Lett. 42, 1604-1607 (2017). Also, S. Hakobyan, R. Maulini, A. Muller et al. addressed this issue in “High performance quantum cascade laser frequency combs at λ˜6 μm based on plasmon-enhanced dispersion compensation”, Opt. Express 28, 20714-20727 (2020).

However, these publications focus on and describe a top plasmon layer only. With only a top cladding design, the plasmon-enhanced dispersion compensation requires unpractically high doping concentrations. This results in a significant increase of waveguide losses. It was found advantageous because much lower losses were achieved, along with the highly doped InP thin plasmon layer to the top cladding, to add a further plasmon layer of highly doped InP to the bottom cladding. The distances between the active region and the plasmon layers are controlled by low doped InP spacers.

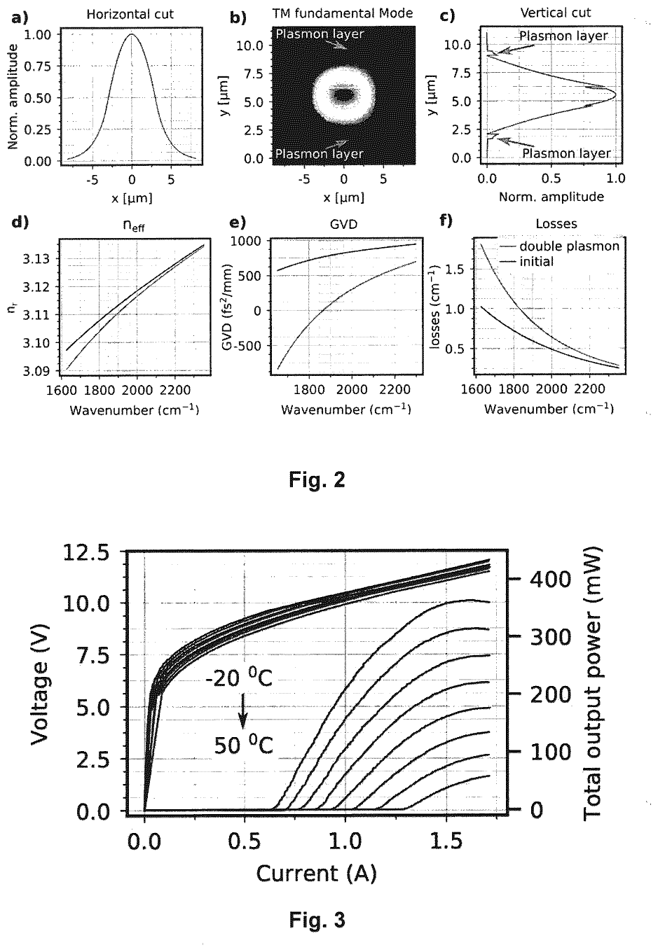

FIG. 2 shows various diagrams of a second embodiment, namely a waveguide structure containing an upper SCL but no lower SCL, The low doped (n=1−4×10¹⁷ cm⁻³) InP:S substrate performs the function of lower cladding; therefore, it was not necessary to grow a lower cladding.

FIG. 2 includes the various diagrams, of which
diagram (a) is a horizontal cut of the 2D norm of the electric field along the center of the structure;
diagram (b) is a 2D norm of the electric field distribution;
diagram (c) is a vertical cut of the norm of the electric field along the center of the structure;
diagram (d) compares (simulated) modal effective refractive indices of a QCL without (upper curve) and with (lower curve) two highly doped plasmon layers, one in the top and one the bottom cladding;
diagram (e) compares (simulated/calculated) group velocity dispersions (GVDs) of a QCL without (upper curve) and with (lower curve) highly doped plasmon layers in the top and the bottom cladding;
diagram (f) compares (simulated/calculated) losses of a QCL without (lower curve) and with (upper curve) highly doped plasmon layers in the top and the bottom cladding.

The gray areas in diagrams (d), (e), and (f) indicate the emission spectrum of the QCL.

The leakage of the fundamental mode to the plasmon layers is visible in the vertical cut of the mode shown in FIG. 2c) while the horizontal cut is kept unchanged as shown in FIG. 2(a). This modifies the dispersion of the structure drastically. FIGS. 2(d) to 2(f) show comparisons of the modal effective refractive index, group velocity dispersion (GVD), and waveguide losses of the fundamental mode for semiconductor structures without and with two plasmon layers. Adding the two plasmon layers according to the invention reduces the dispersion from ˜800 fs²/mm down to ˜200 fs²/mm, while keeping the waveguide losses below 1 cm¹, a reasonable value for efficient comb operation. The composition, thickness, and doping level of the various layers composing the structure, including the plasmon layers, are listed in Table 1.

TABLE 1
Thicknesses and doping levels of the main waveguide layers

| Layer | Material | Thickness [μm] | Doping [cm⁻³] |
|---|---|---|---|
| Contact layer | n⁺-InP | 0.20 | 1.0 × 10¹⁹ |
| Upper cladding | n-InP | 0.20 | 5.0 × 10¹⁸ |
| | n-InP | 0.20 | 1.0 × 10¹⁷ |
| Upper plasmon | n⁺-InP | 0.40 | 2.5 × 10¹⁹ |
| Upper spacer | n-InP | 2.80 | 2.0 × 10¹⁶ |
| Upper SCL | n-InGaAs | 0.15 | 4.0 × 10¹⁶ |
| Active region | InGaAs/AlInAs | 1.573 | 2.2 × 10¹⁶ |
| Lower SCL | — | — | — |
| Lower spacer | n-InP | 2.50 | 3.0 × 10¹⁶ |
| Lower plasmon | n⁺-InP | 0.40 | 2.5 × 10¹⁹ |
| Lower cladding | — | — | — |
| Substrate | n-InP | 350 | 1-4 × 10¹⁷ |

Laser structures of 6 mm length with active region widths from 3.65 μm to 6.15 μm were epitaxial-side-up bonded on AlN submounts with AuSn solder. The back facet was high-reflection (HR) coated while the front facet was left uncoated. The chips-on-submounts were subsequently soldered on copper mounts with In solder.

The QCL chips were operated in a laboratory laser housing with an integrated Peltier cooler for temperature stabilization. The housing allows to control the temperature from −20° C. to +50° C.

The continuous-wave driving current is sent through a bias tee. The RF component of the current of the system is extracted from the AC port of the bias tee and analyzed with an RF spectrum analyzer. For optical power measurements, a calibrated thermopile detector was positioned in front of the output window of the housing. Optical spectra were measured with a Fourier-transform infrared (FTIR) spectrometer. Details on the characterization setup can be found in the above cited paper by S. Hakobyan, R. Maulini, A. Muller et al. who addressed this issue in “High performance quantum cascade laser frequency combs at λ˜6 μm based on plasmon-enhanced dispersion compensation”, Opt. Express 28, 20714-20727 (2020).

FIG. 3 shows continuous-wave Light-Current-Voltage (LIV) curves of a 6.15 μm-wide laser emitting at 5.3 μm at temperatures from ˜20° C. (upper curves) to +50° C. (lower curves). This is the QCL identified above in Table 1 and the associated description.

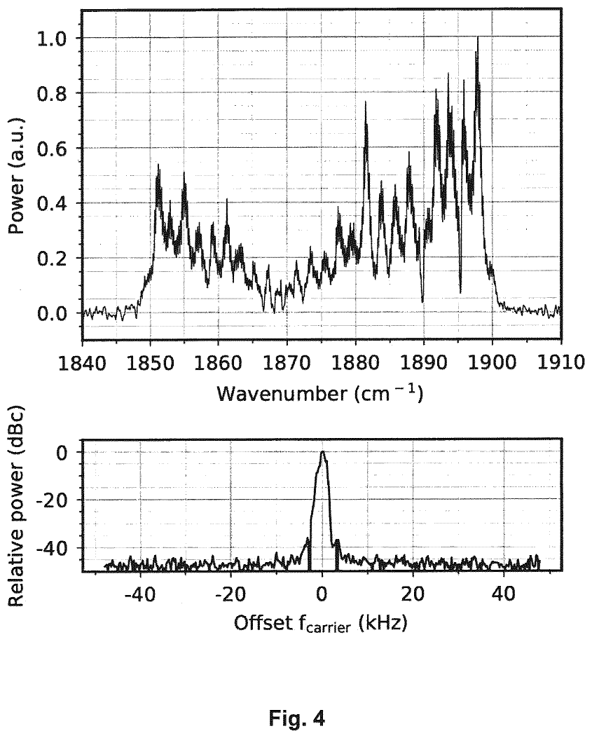

The laser exhibits a maximum output power of 350 mW at ˜20° C. and 70 mW at +50° C., respectively. The temperature coefficients of the threshold current density and slope efficiency are T₀=110 K and T₁=100 K, respectively. The laser exhibits comb operation slightly above the threshold current with optical spectrum centered at ˜1870 cm⁻¹, in excellent agreement with the design goal, with spectral width of ˜50 cm⁻¹. This is illustrated by the diagram in FIG. 4 top, showing the optical spectrum of the laser operating at −20° C. with current of ˜1,2A.

The diagram in FIG. 4 bottom illustrates the offset from the typical intermodal beat frequency at 7.5 GHz with span of ˜80 kHz measured at −10° C. and with current of ˜1.15A. The sharp peak at the carrier or the intermodal beat frequency indicates the coherent frequency comb operation. This peak at of ˜7.5 GHz corresponds to the round-trip frequency in a 6 mm long cavity. With full-width half-max less than 5 kHz it indicates the coherent comb operation.

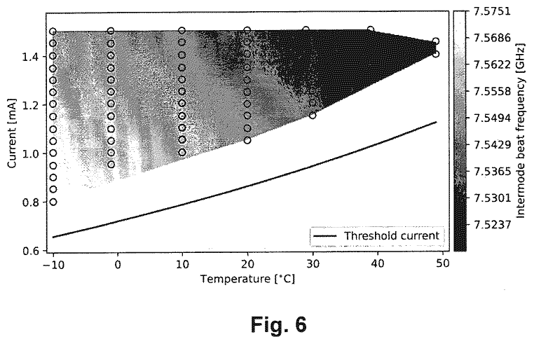

The entire range of the coherent frequency comb operation is depicted in FIG. 6. This figure is the frequency comb operation map of the QCL, showing that comb operation can be observed at all measured temperatures (−10° C. to +50° C.) with hundreds of mA of operational range.

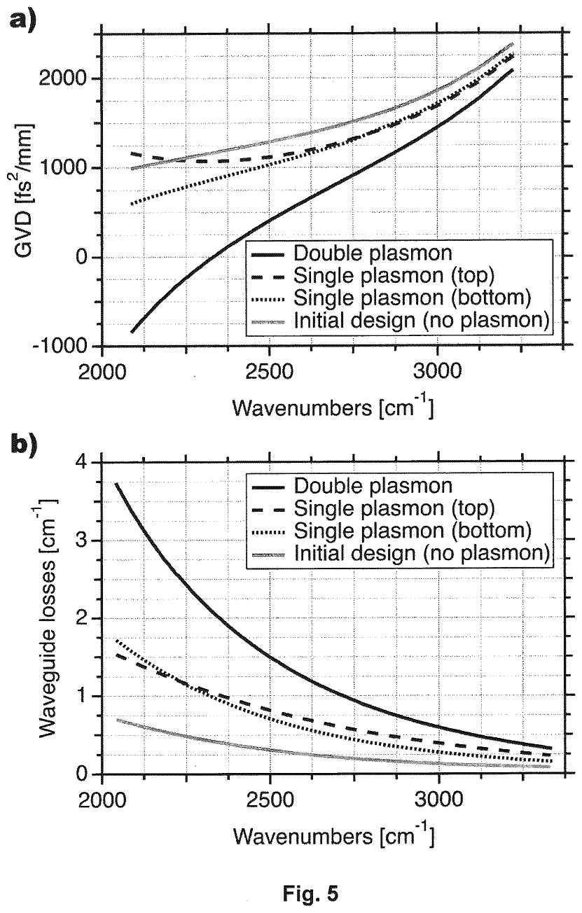

FIG. 5 represents the computed group velocity dispersion (GVD) in FIG. 5a) and the waveguide losses in FIG. 5b) for the fundamental TM mode of a waveguide design at 4 μm. The upper curve in FIG. 5a) and the lower curve in FIG. 5b) depict the respective values for an initial or standard design, i.e. without plasmon layers. The lower curve in FIG. 5a) and the upper curve in FIG. 5b) depict the respective values for a two-plasmon structure, i.e. with a lower and an upper plasmon layer. The middle curves depict the dispersion and losses when only a single plasmon layer is applied. A single plasmon layer only on the bottom cladding appears to result in significantly lower dispersion, see the middle curve in FIG. 5a) branching downwards. For the losses, it does not seem to matter whether a single plasmon layer is installed at the top or the bottom, see the middle curves in FIG. 5b).

By adding the two plasmon layers, the dispersion is reduced by about 850 fs²/mm and it settles at a value below 500 fs²/mM which is considered as a criterion for frequency comb operation according to Faist et al. in “Quantum Cascade Laser Frequency Combs”, Nanophotonics 5, 272-291 (2016).

At the same time, the losses and the doping concentration of the plasmon layers have been kept at an acceptable level for efficient lasing and for fabrication. This comparison shows the efficiency of a two-plasmon structure compared to single plasmon designs.

The experimental results reported above demonstrate that the invention allows to realize high performance QCL combs at wavelengths as short as 5.3 μm. To demonstrate that high performance QCL combs at even shorter wavelengths can be realized, a QCL active region and waveguide for emission at a center wavelength of 4.0 μm was designed and numerical simulations of the optical mode performed to evaluate the group velocity dispersion (GVD) and waveguide losses.

In conclusion, a novel waveguide design for dispersion compensation in short wavelength QCLs for frequency comb operation is shown. Stacking the active region between two highly doped InP plasmon layers allows a precise control of the dispersion of the system while keeping the losses and the doping levels in an acceptable range. The usefulness of the invention by achieving high performance frequency comb operation at a wavelength of 5.3 μm was experimentally demonstrated. That the invention can also be applied to design of high performance QCL combs at wavelengths as short as 4.0 μm was demonstrated by numerical simulation.

1. A semiconductor quantum cascade laser having a waveguide heterostructure with an active core comprising an active region, said active core being sandwiched between two passive layer sets of semiconductor layers in a frequency comb setup, said passive layer sets being located between said core and a contact layer and between a substrate and said core,
wherein
each said passive layer set comprising at least one highly doped semiconductor layer, so-called plasmon layer, with a high carrier concentration and at least one low doped spacer layer with a carrier concentration lower than said high carrier concentration of said plasmon layer.

2. The semiconductor quantum cascade laser of claim 1, wherein
the plasmon layer has a carrier concentration ≥10¹⁹ cm⁻³ and the spacer layer has a carrier concentration <10¹⁸ cm⁻³.

3. A semiconductor quantum cascade laser having a waveguide heterostructure with an active core comprising an active region, said active core being sandwiched between two passive layer sets of semiconductor layers in a frequency comb setup, said passive layer sets being located between said core and a contact layer and between a substrate and said core,
wherein
each said passive layer set comprising at least one so-called plasmon layer with a low refractive index at the emission wavelength of said laser, preferably nₚₗₐₛₘₒₙ<2, and at least one so-called spacer layer with a refractive index higher than said low refractive index, preferably n_{spacer}>2.

4. The semiconductor quantum cascade laser of claim 2, wherein the plasmon layer has a refractive index at the emission wavelength of said laser of nₚₗₐₛₘₒₙ<2 and each adjoining spacer layer has a refractive index of n_{spacer}>2.

5. The semiconductor quantum cascade laser of claim 1, wherein
the core has higher refractive index than the adjoining layer sets.

6. The semiconductor quantum cascade laser of claim 1, wherein
the refractive index of a plasmon layer is lower than that of the adjoining spacer layer and the latter is lower than the refractive index of the core at the emission wavelength of the laser.

7. The semiconductor quantum cascade laser of claim 1, wherein
the difference between the refractive indexes of a plasmonic layer and a spacer layer is larger than the difference between the refractive indexes of the core and said same spacer layer.

8. The semiconductor quantum cascade laser of claim 1, wherein
the composition of the heterostructure is as follows:

| Section | Layer | Material |
|---|---|---|
| Electrode | Metallic layer | |
| | (not shown) | |
| Cap | Contact layer (12) | n+-InP or |
| | | n+-InGaAs |
| Passive layer | Upper cladding (11) | n-InP |
| parts - top | Plasmon layer (10) | n⁺-InP |
| | Spacer layer (9) | n-InP |
| Core | Separate confinement | n-InGaAs |
| | layer (8) | |
| | Active region (7) | InGaAs/AlInAs |
| | Separate confinement | n-InGaAs |
| | layer (5) | |
| Passive layer | Spacer layer (4) | n-InP |
| parts - bottom | Plasmon layer (3) | n⁺-InP |
| Substrate | Substrate (1) | n-InP |

9. The semiconductor quantum cascade laser of claim 8, wherein
only a single upper or lower separate confinement layer, is provided.

10. The semiconductor quantum cascade laser of claim 1, wherein the composition of the heterostructure is as follows:

| Section | Layer | Material |
|---|---|---|
| Electrode | Metallic layer | |
| | (not shown) | |
| Cap | Contact layer (12) | n+-InP or |
| | | n+-InGaAs |
| Passive layer | Upper cladding | n-InP |
| parts - top | Plasmon layer | n⁺-InP |
| | Spacer layer | n-InP |
| Core | none | — |
| | Active region | InGaAs/AlInAs |
| | none | — |
| Passive layer | Spacer layer | n-InP |
| parts - bottom | Plasmon layer | n⁺-InP |
| Substrate | Substrate | n-InP |
